(19) United States
(12) Patent Application Publication
(10) Pub. No.: US 2025/0072091 A1
(43) Pub. Date: Feb. 27, 2025

(54) TRANSISTOR STRUCTURE

(71) Applicant: United Microelectronics Corp., Hsinchu (TW)

(72) Inventors: Shin-Hung Li, Nantou County (TW); Shan-Shi Huang, Hsinchu City (TW)

(73) Assignee: United Microelectronics Corp., Hsinchu (TW)

(21) Appl. No.: 18/465,183

(22) Filed: Sep. 12, 2023

(30) Foreign Application Priority Data
Aug. 25, 2023 (TW) 112132006

(51) Int. Cl. H01L 29/423

(52) U.S. Cl. CPC H01L 29/4238

(57) ABSTRACT

Provided is a transistor structure including a gate, a gate dielectric layer, a source region and a drain region. The gate is disposed on a substrate. The gate dielectric layer is disposed between the gate and the substrate. The source region and the drain region are respectively disposed at two opposite sides of the gate. From a top view above the substrate, the gate has two opposite edges in a first direction intersecting a second direction where a channel length of the transistor structure is located, and each of the two opposite edges has a non-linear shape.

### CROSS-REFERENCE TO RELATED APPLICATION

This application claims the priority benefit of Taiwan application serial no. 112132006, filed on Aug. 25, 2023. The entirety of the above-mentioned patent application is hereby incorporated by reference herein and made a part of this specification.

### BACKGROUND

### Technical Field

The present invention relates to a semiconductor structure, and in particular to a transistor structure.

### Description of Related Art

With the development of semiconductor technology, the demands for the size reduction of a device and the high performance are increasing. In order to solve the electrical problems caused by the size reduction of the gate, the technology of using a metal gate instead of a polysilicon gate has been developed. The method for forming the metal gate may includes the following steps. After forming the dummy polysilicon gate, the dummy polysilicon gate us removed. Then, the metal material is filled as the metal gate. This method is usually called a gate-last process or a replacement metal gate process.

In the above process, after the dummy polysilicon gate is removed, the metal material is filled into the space accommodating the dummy polysilicon gate, and a chemical mechanical polishing (CMP) process is performed to remove the metal material outside the space. However, for a metal gate with a larger area, after the CMP process, it is easy to cause the metal gate to produce the dishing, resulting in a decrease in thickness of the metal gate. As a result, when forming the contact connected to the metal gate, it is easy to have the problem of the metal gate being penetrated, affecting the electrical properties of the device.

### SUMMARY

The present invention provides a transistor structure in which the two opposite edges of the gate have a non-linear shape from the top view above the substrate.

The transistor structure of present invention includes a gate, a gate dielectric layer, a source region and a drain region. The gate is disposed on a substrate. The gate dielectric layer is disposed between the gate and the substrate. The source region and the drain region are respectively disposed at two opposite sides of the gate. From a top view above the substrate, the gate has two opposite edges in a first direction intersecting a second direction where a channel length of the transistor structure is located, and each of the two opposite edges has a non-linear shape.

In an embodiment of the transistor structure of the present invention, from the top view above the substrate, each of the two opposite edges has a plurality of protrusions.

In an embodiment of the transistor structure of the present invention, from the top view above the substrate, a profile of the protrusion is a rectangle.

In an embodiment of the transistor structure of the present invention, from the top view above the substrate, the corners of the protrusion are rounded.

In an embodiment of the transistor structure of the present invention, from the top view above the substrate, the non-linear shape comprises a wave shape.

In an embodiment of the transistor structure of the present invention, from the top view above the substrate, a ratio of a protruding length of the protrusion from the edge to a distance between two adjacent protrusions is between 0.5 and 1.

In an embodiment of the transistor structure of the present invention, the protruding length is between 160 nm and 330 nm.

In an embodiment of the transistor structure of the present invention, each of sidewalls of the gate in the first direction has a plurality of grooves, and each groove is extended from a bottom of the gate to a top of the gate.

In an embodiment of the transistor structure of the present invention, a material of the gate includes polysilicon.

In an embodiment of the transistor structure of the present invention, a material of the gate includes metal.

In an embodiment of the transistor structure of the present invention, the transistor structure further includes an etching stop layer disposed on sidewalls of the gate.

In an embodiment of the transistor structure of the present invention, a material of the etching stop layer includes silicon nitride.

Based on the above, in the transistor structure of the present invention, from the top view above the substrate, the edges of the gate in the direction intersecting the direction where the channel length is located has a non-linear shape. In this way, after the replacement metal gate is performed on the transistor structure, the thickness of the gate may not be decreased, and thus the problem that the gate is penetrated when forming the contact connected with the gate may be effectively avoided.

### BRIEF DESCRIPTION OF THE DRAWINGS

FIG. 1A is a schematic top view of the transistor structure of the first embodiment of the present invention.

FIG. 1B is a perspective view of the transistor structure in FIG. 1A.

FIG. 2 is a schematic top view of the transistor structure of the second embodiment of the present invention.

FIG. 3 is a schematic top view of the transistor structure of the third embodiment of the present invention.

FIG. 4A is a schematic top view of the transistor structure of the fourth embodiment of the present invention.

FIG. 4B is a schematic perspective view of the transistor structure in FIG. 4A.

FIG. 4C is a schematic cross-sectional view along the line A-A in FIG. 4B.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

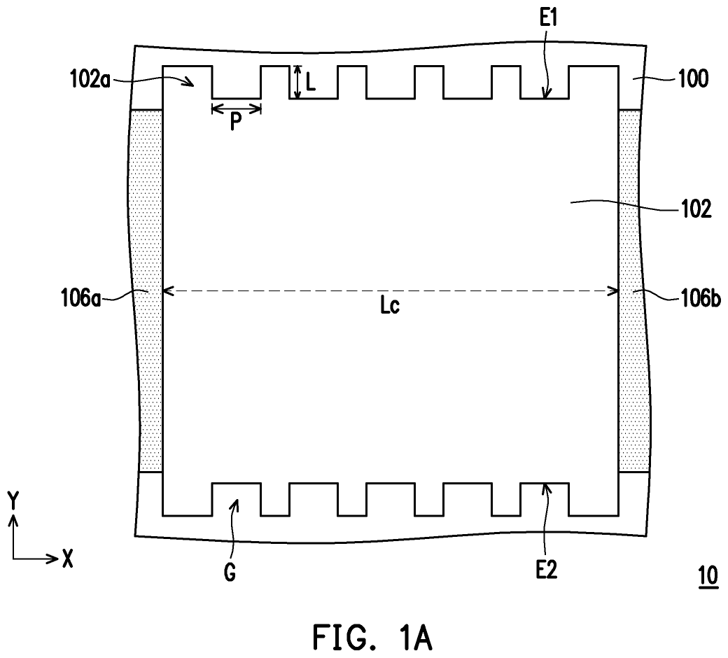

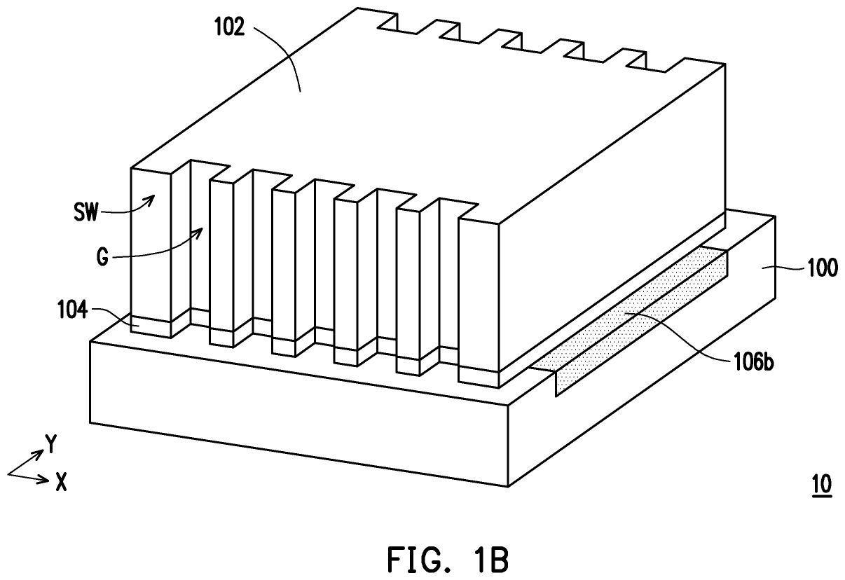

FIG. 1A is a schematic top view of the transistor structure of the first embodiment of the present invention. FIG. 1B is a perspective view of the transistor structure in FIG. 1A.

Referring to FIGS. 1A and 1B, the transistor structure 10 of the present embodiment includes a gate 102, a gate dielectric layer 104, a source region 106a and a drain region 106b. The gate 102 is disposed on a substrate 100. In the present embodiment, the substrate 100 may be a silicon substrate, but the present invention is not limited thereto. In other embodiments, the substrate 100 may be a silicon-on-insulator (SOI) substrate. In the present embodiment, the material of the gate 102 is polysilicon, but the present invention is not limited thereto. In addition, a spacer is disposed on the sidewall of the gate 102. To make the drawings clear, the spacer is not shown in FIGS. 1A and 1B. The source region 106a and the drain region 106b are disposed on two opposite sides of the gate 102 respectively. In the present embodiment, the source region 106a and the drain region 106b are doped regions located in the substrate 100, but the present invention is not limited thereto. In other embodiments, the source region 106a and the drain region 106b may be doped semiconductor layers embedded in the substrate 100 and/or disposed on the substrate 100.

In the transistor structure 10, the region between the source region 106a and the drain region 106b is used as a channel region which has a channel length Lc. In the present embodiment, the channel length Lc is the distance between the source region 106a and the drain region 106b. As shown in FIGS. 1A and 1B, the source region 106a and the drain region 106b are respectively disposed on two opposite sides of the gate 102 in the direction X, so the channel length Lc is located in the direction X.

From the top view above the substrate 100, the gate 102 has two opposite edges E1 and E2 in the direction Y intersecting the direction X, and each of the edge E1 and the edge E2 has non-linear shape as a whole. In detail, each of the edge E1 and the edge E2 has a plurality of protrusion 102a. The protrusions 102a are protruded from the edge E1 and the edge E2. In the present embodiment, the number of the protrusions 102a located at the edge E1 is the same as the number of the protrusions 102a located at the edge E2, but the present invention is not limited thereto.

As shown in FIG. 1B, in the direction Y, each of the two opposite sidewalls SWs of the gate 102 has a plurality of grooves G, and each groove G is extended from the bottom of the gate 102 to the top of the gate 102. That is, the region between the adjacent protrusions 102a is the groove G.

At the edge E1, a protruding length L of the protrusion 102a from the edge E1 may be between 160 nm and 330 nm, and the length L of the protrusions 102a may be the same or different from each other, which is not limited by the present invention. In addition, in the present embodiment, a ratio r of the length L to a distance P between two adjacent protrusions 102a is between 0.5 and 1.

At the edge E2, the protruding length L of the protrusion 102a from the edge E2 may be between 160 nm and 330 nm, and the length L of the protrusions 102a may be the same or different from each other. In addition, a ratio r of the length L to a distance P between two adjacent protrusions 102a is between 0.5 and 1. The length L and the ratio r at the edge E1 may be the same as or different from the length L and the ratio r at the edge E2, which is not limited by the present invention.

In the present embodiment, the sidewalls SW of the transistor structure 10 in the direction Y intersecting the direction X where the channel length Lc is located has a plurality of grooves G, so that the edge E1 and the edge E2 in the direction Y each have a plurality of protrusions 102a and thus have a non-linear shape from the top view above the substrate 100. In this way, when the replacement metal gate process is performed on the transistor structure 10, dishing may not be occurred during the CMP process, so that the formed metal gate may have the same shape and thickness as the gate 102. Therefore, the problem of the metal gate being penetrated when forming a contact with the metal gate may be effectively avoided.

In the present embodiment, the protruding length L of the protrusion 102a from the edge of the gate 102 is between 160 nm and 330 nm. When the length L is greater than 330 nm, the size of the gate 102 may be too large and the layout design of the semiconductor device can be affected. When the length Lis less than 160 nm, the dishing cannot be effectively avoided during the replacement metal gate process. In addition, in the present embodiment, the ratio r of the length L to the distance P between two adjacent protrusions 102a is between 0.5 and 1. When the distance P between two adjacent protrusions 102a is too large, that is, when r is less than 0.5, the dishing cannot be effectively avoided during the metal gate replacement process.

In the present embodiment, the profile of the protrusion 102a is a rectangle from the top view above the substrate 100, but the present invention is not limited thereto. In other embodiments, the profile of the protrusion 102a may be in other shapes from the top view above the substrate 100.

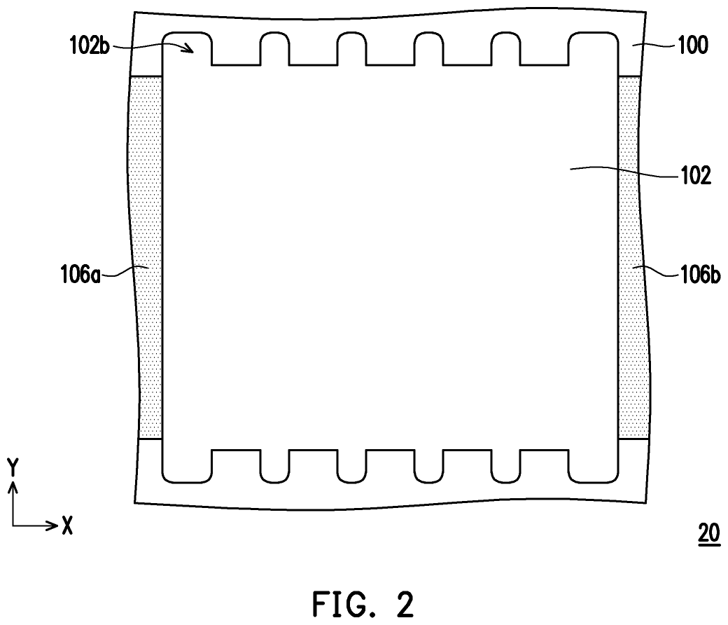

FIG. 2 is a schematic top view of the transistor structure of the second embodiment of the present invention. In the present embodiment, the same device as that of the first embodiment will be denoted by the same reference symbols and will not be described again.

Referring to FIG. 2, in the transistor structure 20 of the present embodiment, from the top view above the substrate 100, the profile of the protrusion 102b is a rectangle, and the corners of the protrusion 102b are rounded. In other embodiments, the corners of the protrusion may also be beveled when the profile of the protrusion 102b is a rectangle.

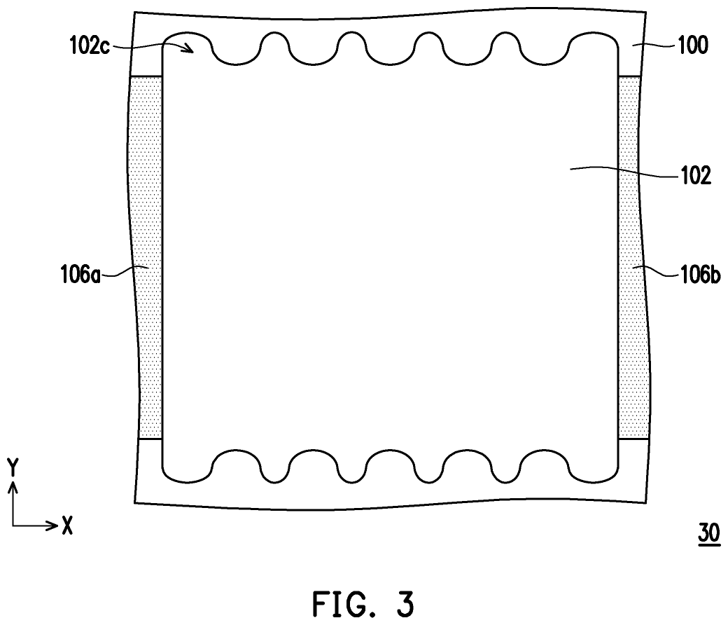

FIG. 3 is a schematic top view of the transistor structure of the third embodiment of the present invention. In the present embodiment, the same device as that of the first embodiment will be denoted by the same reference symbols and will not be described again.

Referring to FIG. 3, in the transistor structure 30 of the present embodiment, from the top view above the substrate 100, the profile of the protrusion 102c is curved such that the edge E1 and the edge E2 are wavy.

In each of the above embodiments, the edge E1 and the edge E2 of the gate 102 have the same form, but the present invention is not limited thereto. In other embodiments, the edge E1 and edge E2 of the gate 102 may have different forms. That is, the Edge E1 and the edge E2 of the gate 102 may each have one of the protrusion 102a, the protrusion 102b and the protrusion 102c.

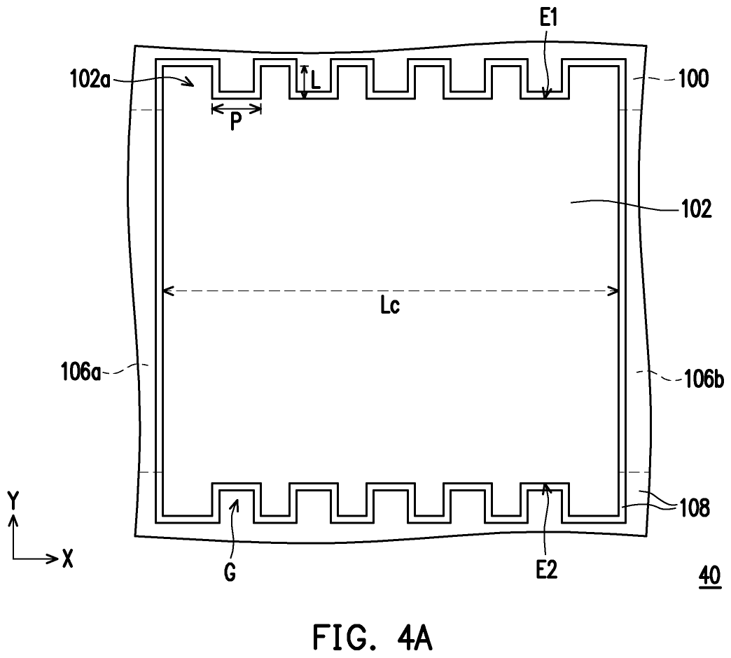

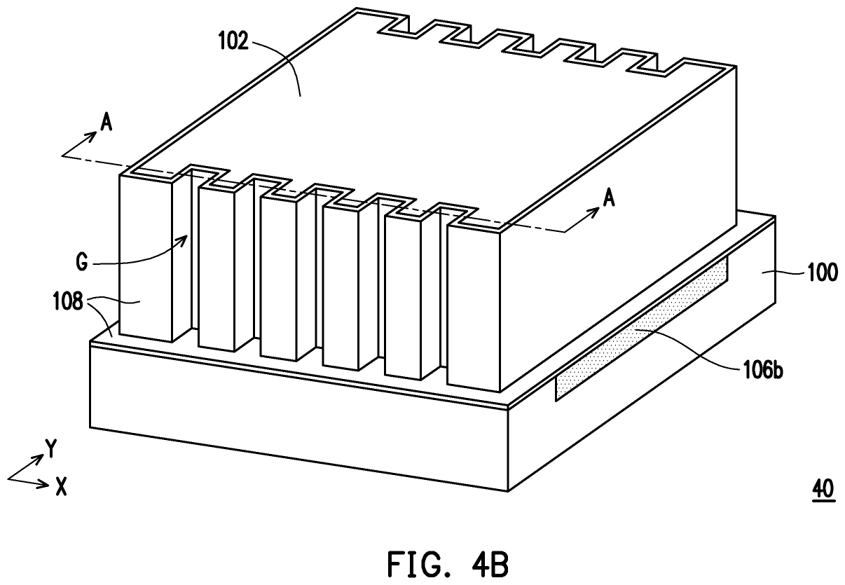

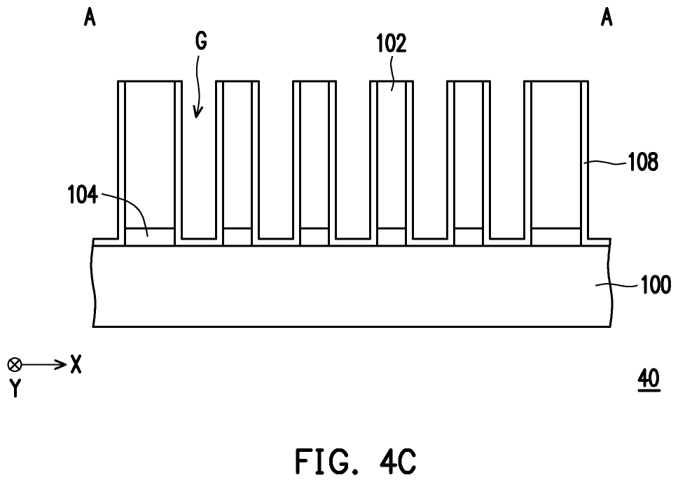

FIG. 4A is a schematic top view of the transistor structure of the fourth embodiment of the present invention. FIG. 4B is a schematic perspective view of the transistor structure in FIG. 4A. FIG. 4C is a schematic cross-sectional view along the line A-A in FIG. 4B. In the present embodiment, the same device as that of the first embodiment will be denoted by the same reference symbols and will not be described again.

Referring to FIGS. 4A, 4B and 4C, in the transistor structure 40 of the present embodiment, an etching stop layer 108 is disposed on the sidewalls SW of the gate 102. In detail, in the present embodiment, the etching stop layer 108 is disposed on the substrate 100 to cover the surface of the substrate 100 and the sidewalls SW of the gate 102 and expose the top surface of the gate 102. In the present embodiment, the material of the etching stop layer 108 includes silicon nitride, but the present invention is not limited thereto. When the etching stop layer 108 is disposed on the sidewalls of the gate 102, the dishing caused by the CMP may be effectively avoided during the replacement metal gate process.

Similarly, the etching stop layer 108 may be disposed on the sidewalls SW of the gate 102 in the second embodiment, the third embodiment, etc.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor structure, comprising:
a gate, disposed on a substrate;
a gate dielectric layer, disposed between the gate and the substrate; and
a source region and a drain region, respectively disposed at two opposite sides of the gate,
wherein, from a top view above the substrate, the gate has two opposite edges in a first direction intersecting a second direction where a channel length of the transistor structure is located, and each of the two opposite edges has a non-linear shape.

2. The transistor structure of claim 1, wherein, from the top view above the substrate, each of the two opposite edges has a plurality of protrusions.

3. The transistor structure of claim 2, wherein, from the top view above the substrate, a profile of the protrusion is a rectangle.

4. The transistor structure of claim 2, wherein, from the top view above the substrate, the corners of the protrusion are rounded.

5. The transistor structure of claim 2, wherein, from the top view above the substrate, the non-linear shape comprises a wave shape.

6. The transistor structure of claim 2, wherein, from the top view above the substrate, a ratio of a protruding length of the protrusion from the edge to a distance between two adjacent protrusions is between 0.5 and 1.

7. The transistor structure of claim 6, wherein the protruding length is between 160 nm and 330 nm.

8. The transistor structure of claim 1, wherein each of sidewalls of the gate in the first direction has a plurality of grooves, and each groove is extended from a bottom of the gate to a top of the gate.

9. The transistor structure of claim 1, wherein a material of the gate comprises polysilicon.

10. The transistor structure of claim 1, wherein a material of the gate comprises metal.

11. The transistor structure of claim 1, further comprises an etching stop layer disposed on sidewalls of the gate.

12. The transistor structure of claim 11, wherein a material of the etching stop layer comprises silicon nitride.
